(19) United States
(12) Patent Application Publication
(10) Pub. No.: US 2026/0344169 A1
(43) Pub. Date: Oct. 29, 2026

(54) ADHESIVE BONDING FOR BIFACIAL AND TANDEM SOLAR CELLS

(71) Applicant: Massachusetts Institute of Technology, Cambridge, MA (US)

(72) Inventors: Moungi G. Bawendi, Cambridge, MA (US); Matthias Grotevent, Somerville, MA (US)

(73) Assignee: Massachusetts Institute of Technology, Cambridge, MA (US)

(21) Appl. No.: 19/685,409

(22) Filed: May 22, 2026

Related U.S. Application Data
(62) Division of application No. 18/843,339, filed on Feb. 28, 2023.
(60) Provisional application No. 63/316,074, filed on Mar. 3, 2022.

(51) Int. Cl. H10K 30/57; H10K 30/40; H10K 30/82

(52) U.S. Cl. CPC H10K 30/57; H10K 30/40; H10K 30/82

(57) ABSTRACT

Disclosed herein are solar cells including a perovskite material and at least one adhesive layer, and methods of making the same. The methods provide solar cells in which transparent conductive oxide(s) have been annealed, and in which the perovskite material is not exposed to elevated temperatures which could degrade its performance.

### CLAIM OF PRIORITY

This application is a divisional application of U.S. patent application Ser. No. 18/843,339, filed Sep. 3, 2024, which is a national stage filing under 35 U.S.C. § 371 of International Patent Application No. PCT/US2023/014043, filed Feb. 28, 2023, which claims priority to U.S. Provisional Patent Application No. 63/316,074, filed Mar. 3, 2022, the contents of each of which are hereby incorporated by reference in their entirety.

### BACKGROUND

Bifacial solar cells harness the energy of direct and indirect (back-side) illumination which increases their yield especially under cloudy conditions as compared to conventional monofacial solar cells. Therefore, bifacial solar cells can absorb about 30% more light than monofacial solar cells depending on the reflectivity of the ground (albedo effect). It is expected that bifacial solar cells will have an increased share of the worldwide solar cell installation within the next decade.

Renewable energies are increasingly important to reach the sustainability goals set by the 2016 Paris Climate Agreement. Most countries (including the US) are increasing their investments into renewable energies. The US solar cell market size was approximately $10bn in 2021 with a 10% growth rate, and the worldwide solar cell market was over $ 100bn.

Transparent conductive electrodes are required in solar cells because they are transparent to light and electrically conductive to extract the photogenerated charge carriers. The conductivity of transparent conductive oxides (TCOs) is limited, leading to an increase in serial resistance and a reduction in solar cell efficiency. While smaller solar cells do not suffer under serial resistance due to their small size, it is a very important parameter for solar modules which are widely used to harness the solar energy.

### SUMMARY

This Summary introduces a selection of concepts in simplified form that are described further below in the Detailed Description. This Summary neither identifies key or essential features, nor limits the scope, of the claimed subject matter.

In one aspect, a solar cell can include a first transparent conductive oxide (TCO) layer, a perovskite layer in electrical communication with the first transparent conductive oxide (TCO) layer, and an adhesive layer between the first transparent conductive oxide (TCO) layer and the perovskite layer.

In another aspect, a tandem solar cell can include a first transparent conductive oxide (TCO) layer, a perovskite layer in electrical communication with the first transparent conductive oxide (TCO) layer, a low-bandgap solar cell, and an adhesive layer between the perovskite layer and the low-bandgap solar cell. The tandem solar cell can include a charge transport layer between the first transparent conductive oxide (TCO) layer and the perovskite layer.

In another aspect, a method of making a solar cell can include forming a first transparent conductive oxide (TCO) layer on a first substrate, forming a first adhesive layer in contact with the first transparent conductive oxide (TCO) layer, forming a second transparent conductive oxide (TCO) layer on a second substrate, forming a charge transport layer on the second transparent conductive oxide layer, forming a perovskite layer in electrical communication with the second transparent conductive oxide (TCO) layer, optionally forming a second adhesive layer in contact with the perovskite layer, and contacting the first adhesive layer to the perovskite layer or to the optional second adhesive layer to form a solar cell.

In another aspect, a method of making a tandem solar cell can include forming a large-bandgap solar cell comprising a first transparent conductive oxide (TCO) layer, forming a first charge transport layer in contact with the first transparent conductive oxide (TCO) layer, forming a perovskite layer in electrical communication with the first charge transport layer, forming a first adhesive layer in contact with the perovskite layer, forming a second transparent conductive oxide layer in contact with a charge transport layer on a low-bandgap solar cell fabricated on a second substrate, forming a second adhesive layer in contact with the second charge transport layer, and contacting the first adhesive layer to the second adhesive layer to form a tandem solar cell. In certain circumstances, the solar cell can include a charge transport material between the first transparent conductive oxide (TCO) layer and the perovskite layer. For example, the charge transport material can be an electron transport material or a hole transport material.

In another aspect, a bifacial solar cell can include a hole transport layer (HTL), a perovskite layer, and an electron transport layer (ETL), wherein the HTL, perovskite, and ETL layers lie between two transparent conductive oxide (TCO) layers, wherein an adhesive layer lies between the TCO layer and HTL layer.

In another aspect, a solar cell can include an electron transport layer (ETL), a perovskite layer, and a copper-indium-gallium-selenide (CIGS) layer, wherein the ETL and CIGS layers lie between a transparent conductive oxide (TCO) layer and a lower conductive layer, wherein an adhesive layer lies between the perovskite and CIGS layers. The lower conductive layer can be a metal, such as, for example, molybdenum.

In another aspect, a method of making the solar cell of the disclosure herein can include bonding the adhesive layer by applying pressure at room temperature. The pressure can be 50 bar, 100 bar, 150 bar, 200 bar, 250 bar, 300 bar, or 400 bar.

In certain circumstances, the adhesive layer can include a charge transport material. The charge transport material can be a hole transport material or an electron transport material.

In certain circumstances, the adhesive layer can include 2,2′,7,7′-tetrakis[N, N-di(4-methoxyphenyl)amino]-9,9′-spirobifluorene (spiro-MeOTAD).

In certain circumstances, the hole transport material can include 2,2′,7,7′-tetrakis[N,N-di(4-methoxyphenyl)amino]-9,9′-spirobifluorene (spiro-MeOTAD).

In certain circumstances, the low-bandgap solar cell can be a silicon solar cell, a CIGS solar cell, or a low-bandgap perovskite solar cell.

In certain circumstances, the large bandgap solar cell can be a perovskite solar cell.

In certain circumstances, the CIGS solar cell can include an upper TCO layer, a CIGS layer, and a lower conductive layer.

In certain circumstances, the CIGS layer can include an adhesive layer and buffer layers, wherein the buffer layers includes an intrinsic zinc oxide layer (i-ZnO) and a cadmium sulfide (CdS) layer.

In certain circumstances, the CIGS solar cell can include one or more buffer layer(s), wherein the one or more buffer layer(s) include an intrinsic zinc oxide layer (i-ZnO) and/or a cadmium sulfide (CdS) layer.

In certain circumstances, the solar cell further can include a copper-indium-gallium-selenide (CIGS) sub-cell, wherein the CIGS subcell can include an upper TCO layer, a CIGS layer, and a lower conductive layer.

In some embodiments, the CIGS layer can include an upper TCO layer, buffer layers, and a lower TCO layer, wherein the buffer layers includes an intrinsic zinc oxide layer (i-ZnO) and a cadmium sulfide (CdS) layer.

In certain circumstances, the upper TCO layer can include ZnO: Al and the lower TCO layer comprises Mo.

In certain circumstances, the first adhesive layer can include a charge transport material. In certain circumstances, the first adhesive layer can include a hole transport material or an electron transport material. In certain circumstances, the second adhesive layer can include a hole transport material or an electron transport material.

In certain circumstances, contacting can occur under pressure.

In certain circumstances, contacting can occur at a temperature below 150 °C.

In certain circumstances, the solar cell is not heated above 150 °C.

In certain circumstances, the bandgap can be adjusted by varying the perovskite composition.

In certain circumstances, the TCO layer can be thermally annealed.

In certain circumstances, the first TCO layer can be annealed prior to forming the first adhesive layer.

In certain circumstances, the second TCO layer can be annealed prior to forming the perovskite layer.

In certain circumstances, the solar cell can be a 2-terminal solar cell.

In certain circumstances, the solar cell can be a 2-terminal tandem solar cell.

The following Description references the accompanying drawings which form a part this application, and which show, by way of illustration, specific example implementations. Other implementations may be made without departing from the scope of the disclosure.

### BRIEF DESCRIPTION OF THE DRAWINGS

FIG. 1 shows the advantages of bifacial solar cells, which are sensitive to both direct solar energy and light from an albedo effect.

FIG. 2 shows conventional solar cell fabrication, which requires bottom-up layer by layer fabrication.

FIG. 3 illustrates an embodiment of fabrication of a bifacial solar cell by adhesive wafer bonding, in which the hole transport material functions as both a hole transport layer and a conductive adhesive. The hole transport material is applied on the perovskite layer and a transparent conductive oxide layer; then, the two layers are bonded together at 200 bar (2900 PSI) at room temperature.

FIG. 4 shows a large area bifacial perovskite solar cell. It uses a metal grid for both mechanical stability and charge extraction.

FIG. 5 shows preliminary bonding results.

FIG. 6A-6E show schematics of (FIG. 6A) adhesive bonding for bifacial and transparent perovskite solar cells; (FIG. 6B) small-area bifacial perovskite solar cell layer sequence comprised of fluorine-doped tin oxide (FTO) or indium-doped tin oxide (ITO) TCO layer, a hole transport layer (HTL), e.g., including 2,2′,7,7′-tetrakis[N,N-di(4-methoxyphenyl)amino]-9,9′-spirobifluorene (spiro-MeOTAD), a perovskite layer, an electron transport layer (ETL), e.g., including SnO₂, and a second TCO layer; (FIG. 6C) layer sequence for 4-terminal tandem solar cells exemplarily with a perovskite solar cell and a CIGS sub-cell; (FIG. 6D) adhesive bonding for 2-terminal tandem solar cell fabrication; and (FIG. 6E) layer sequence exemplarily for a perovskite solar cell and a CIGS sub-cell in a 2-terminal tandem configuration.

FIG. 7 is a schematic of a device described herein.

FIG. 8 is a schematic of a tandem device described herein.

### DETAILED DESCRIPTION

Disclosed herein are bifacial perovskite solar cells, transparent perovskite solar cells in a 4-terminal tandem solar cell configuration, and perovskite solar cells with silicon or copper-indium-gallium-selenide (CIGS) solar cells in a 2-terminal tandem solar cell configuration, and methods of making the same.

Perovskite solar cells are an emerging solar cell technology offering high light conversion efficiencies at low fabrication and energy costs. The active perovskite layer as well as organic charge transport layers are fabricated below 150 °C. Higher temperatures will lead to degradation of those layers.

A solar cell can include a first transparent conductive oxide (TCO) layer proximate to a first charge transport layer; a second TCO layer proximate to a second charge transport layer; a perovskite layer disposed between first and second charge transport layers; and (a) a first plurality of electrically conductive lines disposed between the first TCO layer and the first charge transport layer; or (b) a second plurality of electrically conductive lines disposed between the second TCO layer and second charge transport layer; or (c) both (a) and (b). The cell can include an adhesive layer between the first transparent conductive oxide (TCO) layer and the perovskite layer.

A perovskite material can have formula (Ia):

APbX₃ (Ia)
or formula (Ib):

ASnX₃ (Ib)
where A is an organic or molecular cation (such as ammonium, methylammonium, formamidinium, phosphonium, cesium, etc.), and X is a halide ion (such as I, Br, or Cl).

Alternatively, a perovskite material can have the formula (II):

AₓA′₁₋ₓB_{y}B′_{1-y}O_{3±δ} (II)
where each of A and A′, independently, is a rare earth, alkaline earth metal, or alkali metal, x is in the range of 0 to 1, each of B and B′, independently, is a transition metal, y is in the range of 0 to 1, and δ is in the range of 0 to 1. δ can represent the average number of oxygen-site vacancies (i.e., −δ) or surpluses (i.e., +δ); in some cases, δ is in the range of 0 to 0.5, 0 to 0.25, 0 to 0.15, 0 to 0.1, or 0 to 0.05. For clarity, it is noted that in formula (I), B and B′ do not represent the element boron, but instead are symbols that each independently represent a transition metal. In some cases, δ can be approximately zero, i.e., the number of oxygen-site vacancies or surpluses is effectively zero. The material can in some cases have the formula AB_{y}B′_{1-y}O₃ (i.e., when x is 1 and δ is 0); AₓA′₁₋ₓBO₃ (i.e., when y is 1 and δ is 0); or ABO₃ (i.e., when x is 1, y is 1 and δ is 0). The perovskite can form a two dimensional layer (2D-perovskite) or a three dimensional layer (3D-perovskite).

Rare earth metals include Sc, Y, La, Ce, Pr, Nd, Pm, Sm, Eu, Gd, Tb, Dy, Ho, Er, Tm, Yb, or Lu. Alkaline earth metals include Be, Mg, Ca, Sr, Ba, and Ra. Alkali metals include Li, Na, K, Rb, and Cs. Transition metals include Sc, Ti, V, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au, or Hg. Particularly useful alkaline earth metals can include Ca, Sr, and Ba. Particularly useful transition metals can include first-row transition metals, for example, Cr, Mn, Fe, Co, Ni, and Cu. Representative materials of formula (I) include calcium titanate (CaTiO₃), barium titanate (BaTiO₃), strontium titanate (SrTiO₃), barium ferrite (BaFeO₃), KTaO₃, NaNbO₃, PbTiO₃, LaMnO₃,SrZrO₃, SrHfO₃,SrSnO₃, SrFeO₃, BaZrO₃, BaHfO₃, KNbO₃, BaSnO₃, EuTiO₃, RbTaO₃, GdFeO₃, PbHfO₃, LaCrO₃, PbZrO₃, or LiNbO₃.

Bifacial perovskite solar cells require a transparent electrode (usually transparent conductive oxides) above and below the active perovskite layer. For achieving the highest solar cell performances, the transparent conductive oxides need to be annealed at high temperatures (about 400 °C). While the perovskite solar cell can be fabricated on one transparent conductive oxide as a substrate, the second electrode is usually deposited after the active perovskite layer has been deposited and the required thermal annealing of the electrode cannot be executed without negatively affecting the performance of the perovskite material. This limits the device performance of perovskite bifacial solar cells, transparent perovskite solar cells for 4-terminal tandem solar cells, and 2-terminal perovskite tandem solar cells.

The fabrication techniques disclosed herein (e.g., adhesive bonding) allow thermal annealing of transparent conductive oxide electrodes, and separately allow combination of the electrodes with a half-finished perovskite solar cell. In this way, the benefits of a (non-annealed) perovskite solar cell and of annealed transparent conductive oxide electrodes can be combined in one device.

The hole transport layer can include Spiro-OMeTAD, PEDOT: PSS, PTAA (poly[bis(4-phenyl)(2,4,6-trimethylphenyl)amine]) or P3HT. The hole transport layer can be an adhesive, for example, a pressure-sensitive adhesive.

In some embodiments, the solar cell can include a first adhesive layer disposed between a first TCO layer and a first plurality of electrically conductive lines. The first adhesive layer can include titanium (Ti) or chromium (Cr). The first adhesive layer can include an electrically conductive material. The first adhesive layer can include an electrically insulating material.

In some embodiments, the solar cell can include an adhesive layer disposed between a second TCO layer and a second plurality of electrically conductive lines. The second adhesive layer can include titanium (Ti), thiophenol, hexanethiol, or trioctylphosphine oxide. The second adhesive layer can include an electrically conductive material. The second adhesive layer can include an electrically insulating material.

In certain circumstances, the adhesive layer can be a charge transport layer, for example, a hole transport layer or an electron transport layer.

The electron transport layer can include tin oxides, zinc-tin oxides, magnesium-tin oxides, aluminum-tin oxides, or tin-titanium oxides.

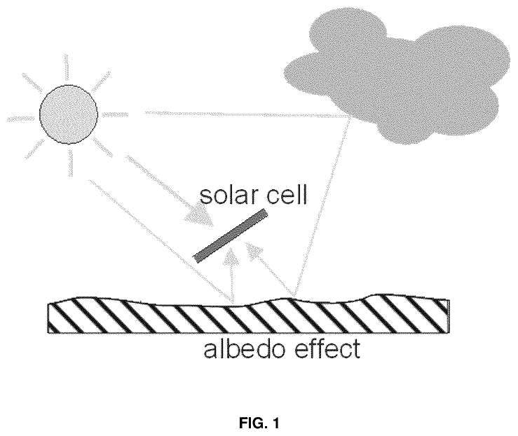

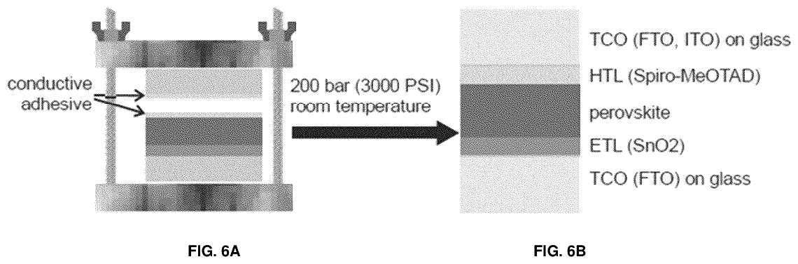

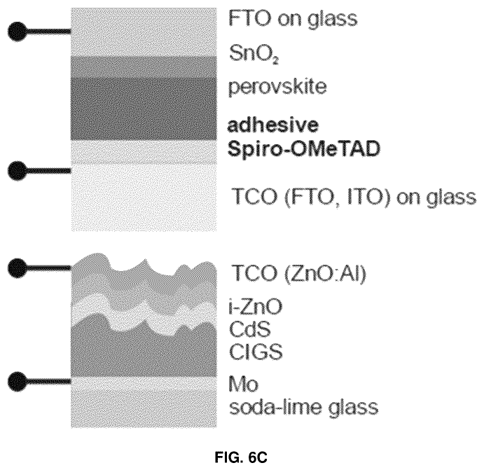

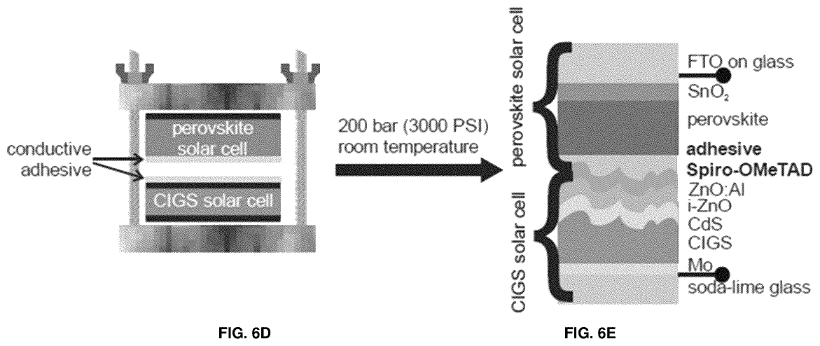

In the case of 2-terminal tandem solar cell, the adhesive bonding combines the perovskite sub-cell (fabricated on a previously thermally annealed transparent conductive oxide electrode) with a silicon or CIGS sub-cell. FIG. 6A shows the bonding of a thermally annealed, transparent conductive electrode on top of a perovskite sub-cell by applying pressure. In this embodiment, the organic hole transporting layer serves both as an adhesive in the bonding process and as a hole transporting layer in the fabricated perovskite solar cell (FIG. 6B). The resulting bifacial perovskite solar cell can be individually used for example in stationary applications or space applications utilizing the albedo effect (FIG. 1) or can be placed on top of a silicon or CIGS solar cell as shown in FIG. 6C for 4-terminal tandem solar cell application. The perovskite bandgap needs to be adjusted according to the intended application, which can easily be achieved by varying the perovskite composition.

FIG. 6D shows the bonding of a perovskite sub-cell with a CIGS (or silicon, or low-bandgap perovskite) sub-cell creating a 2-terminal tandem solar cell as shown in FIG. 6E. Typically, 2-terminal tandem solar cells are fabricated layer-by-layer starting from the silicon or CIGS sub-cell, a method which does not allow for the annealing step of the top electrode. In contrast, FIGS. 6D-6E illustrate a perovskite sub-cell which has been individually fabricated on top of a (previously annealed) transparent conductive oxide substrate, and then adhered to the silicon or CIGS sub-cell, allowing for improved performance of the tandem solar cell device.

FIGS. 6A-6E illustrate adhesive material on both sides of the stacks (i.e., on both faces of the sub-cells to be joined). In some embodiments, the adhesive material can also be applied on only one face, e.g., the perovskite sub-cell or the transparent conductive electrode.

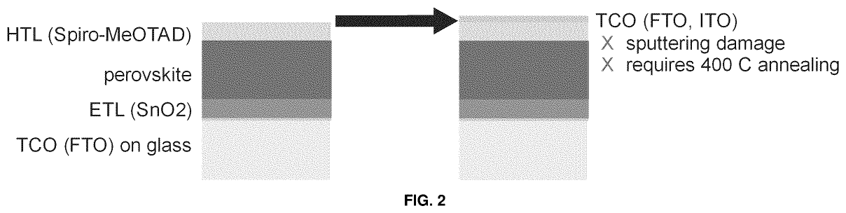

Bifacial perovskite solar cells are conventionally fabricated bottom-up by a layer-by-layer fabrication scheme, as illustrated in FIG. 2. This means that the top, transparent electrode needs to be fabricated on top of the hole-transporting layer and perovskite layer. Sputtering techniques as well as thermal annealing of the transparent top electrode cannot be applied without damaging the underlying layers. However, thermal annealing is crucial to the transparent electrode for achieving high conductivity and transparency required for an overall high solar cell efficiency.

The same problem arises for tandem solar cells with bottom silicon or CIGS solar cells and a perovskite top solar cell. The perovskite top solar cell needs a transparent top electrode. Typically, the transparent top electrode is deposited in the last fabrication step on top of underlying perovskite films and, again, the required thermal annealing of the top transparent electrode is not feasible as it would result in severe damage of the underlying layers.

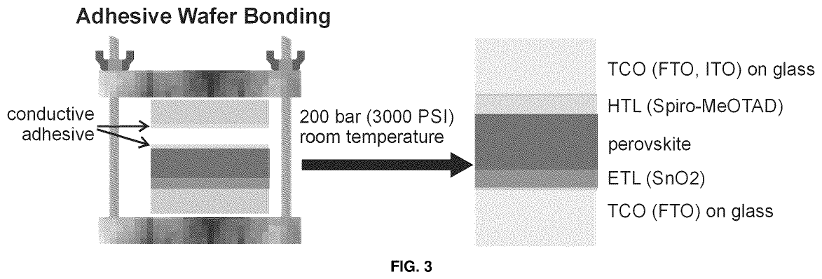

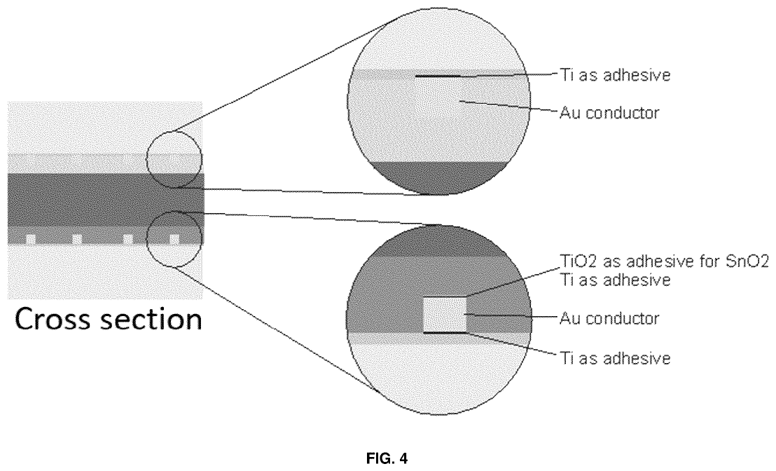

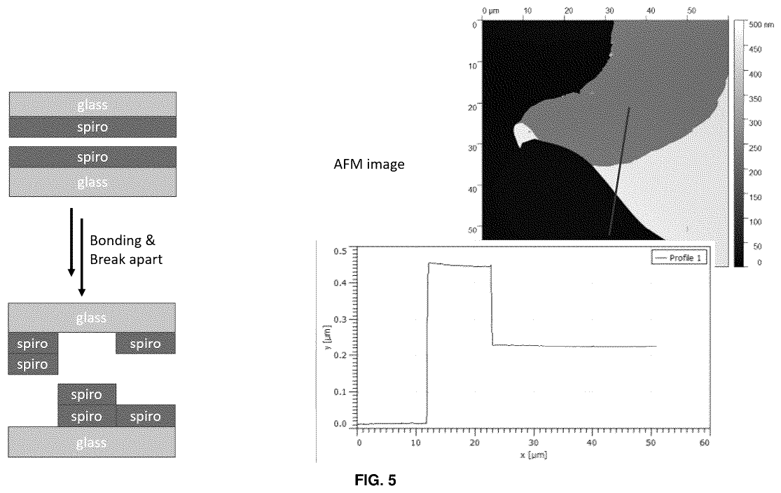

The method disclosed herein (e.g., as illustrated in FIGS. 3-4) circumvents these problems by starting with an annealed transparent electrode and connecting the electrode to the perovskite solar cell with adhesive wafer bonding. In some embodiments, the hole transport layer (e.g., spiro-MeOTAD) can function as the adhesive as well as the hole transporting layer in the fabricated device. The bonding process functions at room-temperature under moderate pressure.

Bifacial as well as tandem solar cells can also be applied for niche markets for satellite applications. Tandem solar cells may also be used for electric cars, and hybrid and electric airplanes/air-taxis.

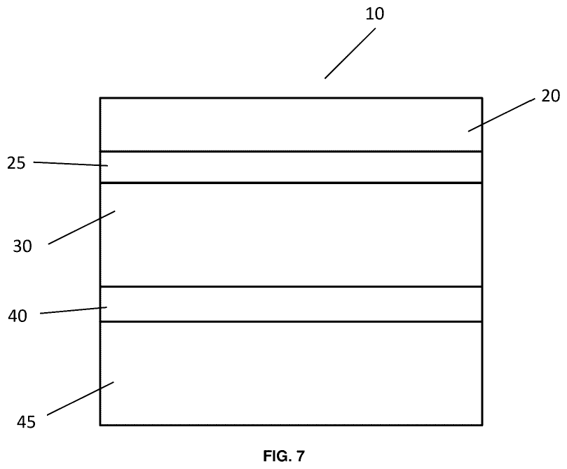

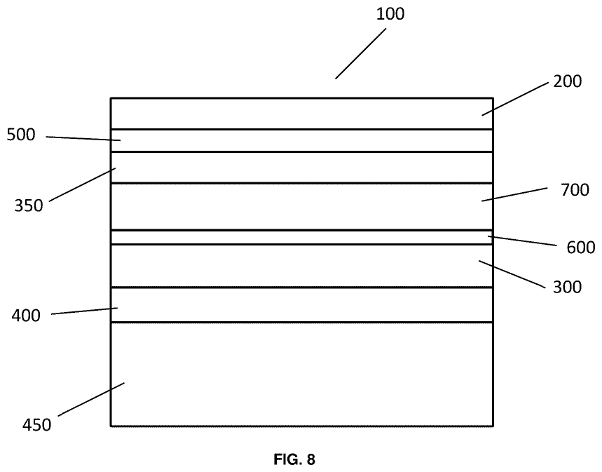

An example of a solar cell device is shown in FIGS. 7-8. Referring to FIG. 7, solar cell device 10 includes transparent conductive layer 20 and transparent conductive layer 45. Each transparent conductive layer can include a transparent conductive oxide (TCO). Hole transport layer (HTL) 25 is adjacent to transparent conductive layer 20 and perovskite layer 30 opposite transparent conductive layer 20. Hole transport layer (HTL) 25 is an adhesive layer. Perovskite layer 30 can include a 2D-perovskite, a 3D-perovskite, or combinations thereof. Electron transport layer (ETL) 40 is adjacent to transparent conductive layer 45 and perovskite layer 30 opposite transparent conductive layer 45. Referring to FIG. 8, tandem solar cell device 100 includes transparent conductive layer 200 and conductive layer 450. Each transparent conductive layer can include a transparent conductive oxide (TCO). Each conductive layer can include a metal. Hole transport layer (ETL) 400 is adjacent to conductive layer 450 and first semiconductor layer 300 opposite transparent conductive layer 450. Electron transport layer (ETL) 500 is adjacent to transparent conductive layer 200 and second semiconductor layer 350 opposite transparent conductive layer 200. Transparent conductive layer 600 can optionally be adjacent to second semiconductor layer 300. Hole transport layer (HTL) 700 is adjacent to transparent conductive layer 200 and second semiconductor layer 350 opposite transparent conductive layer 600. Hole transport layer (HTL) 700 is an adhesive. second semiconductor layer 350 can include a perovskite. First semiconductor layer 300 can be a low-bandgap solar cell.

### EXAMPLES

### Device Preparation

A first substrate consisting of fluorine doped tin oxide (FTO) on glass was ultrasonic cleaned with a 1:50 Hellmanex III:deionized water solution for 10 minutes, followed by 10 minutes in deionized water at 50 °C, 10 minutes in fresh deionized water at 50 °C, 10 minutes in acetone at 50 °C, and 10 minutes in 2-propanol at 50 °C. The cleaned substrate was dried using an air-drying gun.

The cleaned first substrate was immerged in a solution containing 625 mg urea, 138 mg SnCl₂·2H₂O, 50 mL deionized water, 12.5 μL thioglycolic acid, and 625 μL hydrochloric acid (37 wt %) for 14 hours at 65 °C. The first substrate (glass/FTO/SnO₂) was ultrasonic cleaned for 10 minutes in deionized water at 50 °C, 10 minutes in fresh deionized water at 50 °C, 10 minutes in acetone at 50 °C, and 10 minutes in 2-propanol at 50 °C. The cleaned substrate was dried using an air-drying gun.

Subsequently, 60 nm thick aluminum metal reinforcement was deposited on top of the first substrate (glass/FTO/SnO₂) by thermal evaporation with an evaporation speed of about 5 nm/s.

The first substrate (glass/FTO/SnO₂&Al reinforcement) was annealed at ambient air for 1 hour at 170 °C, followed by oxygen plasma cleaning for 10 minutes at reduced pressure. A potassium chloride solution was deposited by spin coating (10 mM KCl in deionized water; spin coater setting: 3000 rpm₍ₘₐₓ₎ for 20 seconds). Followed by an annealing step at 100 °C for 10 minutes.

The first substrate (glass/FTO/SnO₂&Al reinforcement) was transferred into a dry air deposition chamber with a relative humidity below 1%. A perovskite solution consisting of 704 mg lead iodide (PbI₂), 240 mg formamidinium iodide (FAI), 9 mg methylammonium lead bromide (MAPbBr₃), 25 mg methylammonium chloride (MACl), 890 μL N,N-dimethylformamide, and 110 μL dimethyl sulfoxide was deposited at 5000 rpm₍ₘₐₓ₎ for 30 seconds by spin coating. During this spin coating process, 600 μL diethyl ether were deposited dynamically to initiate the perovskite crystallization process. The perovskite film was annealed at 100 °C for 1 hour followed by 150 °C for 5 minutes. Subsequently, a 2D perovskite passivation layer was fabricated by spin coating (4000 rpm₍ₘₐₓ₎ for 30 s) a 15 mM n-hexylammonium bromide solution in chloroform, followed by annealing at 100 °C for 10 minutes.

The hole transporting layer (HTL) consisting of a mixture of spiro-MeOTAD with about 10 mol % 2,2′,7,7′-Tetrakis[N,N-di(4-methoxyphenyl)amino]-9,9′-spirobifluorene bis(trifluoromethanesulfonyl)imide ([Spiro-MeOTAD]₁[TFSI]₁) in chlorobenzene (ca 70 mg/mL) was spin coated at 3000 rpm₍ₘₐₓ₎ for 20 seconds.

The first substrate layer sequence is as follows: glass/FTO/SnO₂&Al reinforcement/perovskite/2D perovskite/HTL.

A second substrate consisting of polyethylene terephthalate coated with indium tin oxide (PET/ITO) was ultrasonic cleaned with a 1:50 Hellmanex III: deionized water solution for 10 minutes, followed by 10 minutes in deionized water at 50 °C, 10 minutes in fresh deionized water at 50 °C, 10 minutes in acetone at 50 °C, and 10 minutes in 2-propanol at 50 °C. The cleaned substrates were dried using an air-drying gun.

60 nm thick aluminum metal reinforcement was deposited on top of the ITO by thermal evaporation with an evaporation speed of about 5 nm/s. Afterwards, the second substrate (PET/ITO&Al reinforcement) was oxygen plasma cleaned for 10 minutes at reduced pressure. Subsequently, a hole transport layer of SpiroMeOTAD with [Spiro-MeOTAD]₁[TFSI]₁ in chlorobenzene was deposited by spin coating at 3000 rpm₍ₘₐₓ₎ for 20 seconds in a dry air atmosphere. The second substrate layer sequence is as follows: PET/ITO&Al reinforcement/HTL.

The second substrate was placed upside down on top of the first substrate. The two HTL layers were merged by adhesive bonding: applying pressure on to the substrate stack at room temperature. The full layer sequence is as follows: glass/FTO/SnO₂&Al reinforcement/perovskite/2D perovskite/HTL/ITO&Al reinforcement/PET. The total HTL layer thickness is the combined thicknesses of the two individual HTL layers.

### Adhesive Wafer Bonding

The second substrate was placed upside down on top of the first substrate, therefore, the two HTL layers (out of the same material) are facing each other. For best bonding performances, the samples were fabricated as smooth as possible, and as flat as possible with keeping a foreign particle contamination as low as possible. A flat and smooth surface ensures a large contact area at the interface between the two HTL layers resulting in a larger bifacial solar cell. The stack was placed in a hydraulic press and a pressure of about 150 bar (2176 PSI) was applied for 5 minutes at room temperature.

The resulting layer sequence is as follows: glass/FTO/SnO₂&Al reinforcement/perovskite/2D perovskite/HTL/ITO&Al reinforcement/PET. The total HTL layer thickness is the combined thicknesses of the two individual HTL layers.

### Electrical Measurement

The FTO and ITO electrodes were electrically contacted through the aluminum reinforced metal structure to ensure a good electrical contact. Under illumination (AM 1.5G, 100 mW/cm²), a voltage was ramped from 0 V to 1.2 V (forward scan) or from 1.2 V to 0 V (reverse scan) while the current was measured. The measurement was performed when the bifacial solar cell was illuminated through the glass side. A separate pair of measurements with the same measurement conditions was performed but the solar cell was illuminated through the PET side.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. It should also be understood that the appended drawings are not necessarily to scale, presenting a somewhat simplified representation of various features and basic principles of the invention.

1-5. (canceled)

6. A tandem solar cell comprising:
a first transparent conductive oxide (TCO) layer;
a perovskite layer in electrical communication with the first transparent conductive oxide (TCO) layer;
a low-bandgap solar cell; and
an adhesive layer between the perovskite layer and the low-bandgap solar cell.

7-11. (canceled)

12. A method of making a solar cell, comprising:
forming a first transparent conductive oxide (TCO) layer on a first substrate;
forming a first adhesive layer in contact with the first transparent conductive oxide (TCO) layer;
forming a second transparent conductive oxide (TCO) layer on a second substrate;
forming a perovskite layer in electrical communication with the second transparent conductive oxide (TCO) layer;
optionally forming a second adhesive layer in contact with the perovskite layer; and
contacting the first adhesive layer to the perovskite layer or to the optional second adhesive layer to form a solar cell.

13. The method of claim 12, wherein the first adhesive layer and/or the second adhesive layer comprise a hole transport material.

14. The method of claim 12, wherein contacting occurs under pressure.

15. The method of claim 12, wherein contacting occurs at a temperature below 150 °C.

16. The method of claim 12, wherein the first TCO layer is annealed prior to forming the first adhesive layer.

17. The method of claim 12, wherein the second TCO layer is annealed prior to forming the perovskite layer.

18. A method of making a tandem solar cell, comprising:
forming a large bandgap solar cell comprising a first transparent conductive oxide (TCO) layer;
forming a first charge transport layer in contact with the first transparent conductive oxide (TCO) layer;
forming a perovskite layer in electrical communication with the first charge transport layer;
forming a first adhesive layer in contact with the perovskite layer;
forming a second transparent conductive oxide layer in contact with a charge transport layer on a low-bandgap solar cell fabricated on a second substrate;
forming a second adhesive layer in contact with the second charge transport layer; and
contacting the first adhesive layer to the second adhesive layer to form a tandem solar cell.

19. The method of claim 18, wherein the low-bandgap solar cell is a silicon solar cell, a CIGS solar cell, or a low-bandgap perovskite solar cell.

20. A bifacial solar cell comprising a hole transport layer (HTL), a perovskite layer, and an electron transport layer (ETL), wherein the HTL, perovskite, and ETL layers lie between two transparent conductive oxide (TCO) layers, wherein an adhesive layer lies between the TCO layer and HTL layer.

21. The bifacial solar cell of claim 20, wherein the bifacial solar cell is a 2-terminal solar cell.

22. A solar cell comprising an electron transport layer (ETL), a perovskite layer, and a copper-indium-gallium-selenide (CIGS) layer, wherein the ETL and CIGS layers lie between a transparent conductive oxide (TCO) layer and a lower conductive layer, wherein an adhesive layer lies between the perovskite and CIGS layers.

23. The solar cell of claim 22, wherein the CIGS layer further comprises an adhesive layer and buffer layers, wherein the buffer layers comprise an intrinsic zinc oxide layer (i-ZnO) and a cadmium sulfide (CdS) layer.

24. The solar cell of claim 22, wherein the bifacial solar cell is a 2-terminal tandem solar cell.

25. The solar cell of claim 22, wherein the adhesive layer comprises 2,2′,7,7′-tetrakis[N, N-di(4-methoxyphenyl)amino]-9,9′-spirobifluorene (spiro-MeOTAD).

26-30. (canceled)

31. A method of making the solar cell of claim 22, wherein the adhesive layer is bonded by applying pressure at room temperature.

32. The method of claim 31, wherein the solar cell is not heated above 150 °C.

33. The method of claim 31, wherein the bandgap is adjusted by varying the perovskite composition.

34. The method of claim 31, wherein the TCO layer is thermally annealed.
